(19) United States
(12) Patent Application Publication
(10) Pub. No.: US 2017/0315393 A1
(43) Pub. Date: Nov. 2, 2017

(54) LIQUID CRYSTAL DISPLAY DEVICE AND METHOD FOR MANUFACTURING SAME

(71) Applicant: Sharp Kabushiki Kaisha, Sakai City, Osaka (JP)

(72) Inventors: ISAMU MIYAKE, Sakai City (JP); YOHSUKE KANZAKI, Sakai City (JP)

(73) Assignee: Sharp Kabushiki Kaisha

(21) Appl. No.: 15/527,683

(22) PCT Filed: Nov. 19, 2015
(86) PCT No.: PCT/JP2015/082561

§ 371 Date: May 17, 2017

(30) Foreign Application Priority Data
Nov. 20, 2014 (JP) JP 2014-235561

(51) Int. Cl. G02F 1/1368; G02F 1/1343; H01L 27/12; H01L 29/24; G02F 1/1337; H01L 29/786

(52) U.S. Cl. CPC G02F 1/1368; G02F 1/13378; G02F 1/134363; G02F 1/13439; H01L 27/1225; H01L 29/7869; H01L 29/24; G02F 1/133723; H01L 27/127; G02F 2001/133715; G02F 2001/133742; G02F 2201/124; G02F 2202/10; G02F 2001/134372

(57) ABSTRACT

The present invention provides a liquid crystal display device in which display unevenness is suppressed by preventing degradation of TFT characteristics due to photo-alignment treatment. The liquid crystal display of the present invention includes: a thin-film transistor substrate; and a liquid crystal layer, the thin-film transistor substrate including a thin-film transistor having a channel etch structure and an alignment film, the thin-film transistor including a gate electrode, a gate insulating film, a channel layer containing an oxide semiconductor, and a pair of a source electrode and a drain electrode in the stated order, the alignment film including at least one selected from the group consisting of a cinnamate structure, a chalcone structure, an azobenzene structure, a stilbene structure, a coumarin structure, and a phenyl ester structure.

### TECHNICAL FIELD

The present invention relates to a liquid crystal display device and a method for manufacturing the same. More specifically, the present invention relates to a liquid crystal display device including an oxide semiconductor in a thin-film transistor substrate, and a method for manufacturing the liquid crystal display device.

### BACKGROUND ART

Liquid crystal display devices are display devices utilizing a liquid crystal composition for display. According to a typical display mode thereof, light is incident on a liquid crystal panel including a liquid crystal composition sealed in between a pair of substrates and a voltage is applied to the liquid crystal composition to change the alignment of liquid crystal molecules, thereby controlling the amount of light passing through the liquid crystal panel. Such liquid crystal display devices have advantageous characteristics such as thin profile, light weight, and low power consumption and thus are applied in various fields.

Conventionally used materials for a channel layer included in a thin-film transistor (TFT) that is provided in each pixel of a liquid crystal display device are silicon materials such as polycrystalline silicon and amorphous silicon. Recently, oxide semiconductors have been used as materials for a channel layer with an aim of improving the performance of the TFT.

Along with the recent development of higher definition liquid crystal display devices, the area of a pixel has been reduced. A pixel-driving TFT is therefore desired to be smaller to increase the aperture ratio of the pixel. A known structure advantageous for downsizing of the TFT is channel-etch (CE) structure.

The alignment of liquid crystal molecules in a state where no voltage is applied is normally controlled by an alignment film subjected to alignment treatment. Conventionally, rubbing is widely employed as an alignment treatment technique. Recently, research and development have been made on a photo-alignment method that enables contactless alignment treatment (for example, see Patent Literature 1).

### CITATION LIST

### Patent Literature

Patent Literature 1: WO 2012/050177

### SUMMARY OF INVENTION

### Technical Problem

In the case where a photolysis alignment film including a cyclobutane structure is used for the photo-alignment treatment, the threshold voltage (Vth) of the TFT may be lowered (negative shift). The use of an electrostatic chuck or a transfer step in production of liquid crystal display devices may cause static generation, and through a pixel transistor subjected to the negative shift, information of the static is unintendedly written into the corresponding pixel. As a result, a direct current (DC) potential applied to the liquid crystal causes a residual DC voltage in the liquid crystal, leading to display unevenness (nonuniform DC charging).

The present invention has been devised under the current situation in the art, and aims to provide a liquid crystal display device in which display unevenness is suppressed by preventing degradation of TFT characteristics due to photo-alignment treatment, and a method for producing the liquid crystal display device.

### Solution to Problem

In the research on the degradation of TFT characteristics due to photo-alignment treatment, the inventors of the present invention noted that TFT characteristics are degraded when the TFT has a channel etch (CE) structure and an oxide semiconductor is used in a channel layer. As a result of study on the cause of the degradation of TFT characteristics, they found the followings. When the channel layer includes an oxide semiconductor, the oxide semiconductor is damaged during a process of forming the CE structure. The damaged oxide semiconductor generates electron-hole pairs upon irradiation with light. Due to the generation of electron-hole pairs, current-voltage characteristics (I-V characteristics) of the TFT are shifted to the negative side, leading to display unevenness. As a result of further study, it was found out that the damaged oxide semiconductor generates electron-hole pairs when irradiated with light having a wavelength shorter than 270 nm but does not generate electron-hole pairs when irradiated with light having a wavelength of 270 nm or longer.

The inventors of the present invention accordingly found out that degradation of TFT characteristics can be prevented by using, as a photofunctional group of the alignment film, at least one of a cinnamate structure, a chalcone structure, an azobenzene structure, a stilbene structure, a coumarin structure, and a phenyl ester structure which are active against light having a wavelength of 270 nm or longer, instead of a cyclobutane structure that is active against light having a wavelength shorter than 270 nm (short-wavelength ultraviolet rays). The inventors of the present invention have thus solved the above problems to complete the present invention.

One aspect of the present invention may be a liquid crystal display device including a thin-film transistor substrate and a liquid crystal layer, the thin-film transistor substrate including a thin-film transistor having a channel etch structure and an alignment film, the thin-film transistor including a gate electrode, a gate insulating film, a channel layer containing an oxide semiconductor, and a pair of a source electrode and a drain electrode in the stated order, the alignment film including at least one selected from the group consisting of a cinnamate structure, a chalcone structure, an azobenzene structure, a stilbene structure, a coumarin structure, and a phenyl ester structure.

Another aspect of the present invention may be a method for producing a liquid crystal display device including a thin-film transistor substrate that includes a bottom gate type thin-film transistor and an alignment film, and a liquid crystal layer, including: step (A) of forming a gate electrode; step (B) of forming a gate insulating film; step (C) of forming a channel layer containing an oxide semiconductor; step (D) of forming a pair of a source electrode and a drain electrode by forming a metal film on the gate insulating film and on the channel layer and partly removing the metal film formed on the channel layer by etching; and step (E) of forming the alignment film that includes at least one selected from the group consisting of a cinnamate structure, a chalcone structure, an azobenzene structure, a stilbene structure, a coumarin structure, and a phenyl ester structure, the step (E) including irradiation with light having a wavelength of 270 nm or longer.

### Advantageous Effects of Invention

In the liquid crystal display device of the present invention, since the photofunctional group contained in the alignment film is a group which enables the alignment treatment with light having a wavelength of 270 nm or longer, the photo-alignment treatment can be performed without photoexcitation of the defect level of the oxide semiconductor included in the channel layer in the thin-film transistor having a channel etch structure. Degradation of the current-voltage (I-V) characteristics of the TFT due to the photo-alignment treatment can be thus prevented. This can prevent nonuniform DC charging due to TFT characteristics, leading to a liquid crystal display device excellent in display quality.

In the method for producing a liquid crystal display device of the present invention, the alignment treatment can be performed by irradiation with light having a wavelength of 270 nm or longer, and therefore, photoexcitation of the defect level of the oxide semiconductor included in the channel layer can be prevented in the thin-film transistor having a channel etch structure. In this manner, degradation of the current-voltage (I-V) characteristics of the TFT due to the photo-alignment treatment can be prevented. This can prevent nonuniform DC charging due to TFT characteristics, leading to production of a liquid crystal display device excellent in display quality.

### BRIEF DESCRIPTION OF DRAWINGS

FIG. 1 is a cross-sectional view schematically illustrating a structure of a liquid crystal display device of Example 1.

FIG. 2 is a cross-sectional view schematically illustrating a thin-film transistor substrate of Example 1.

FIG. 3 is a plan view schematically illustrating a pixel of the thin-film transistor substrate of Example 1.

FIG. 4 is a view showing an irradiation spectrum of an alignment treatment in Example 1.

FIG. 5 is a graph showing current-voltage characteristics of a TFT of Example 1 analyzed before and after exposure for the alignment treatment.

FIG. 6 is a view showing an irradiation spectrum of an alignment treatment in Comparative Example 1.

FIG. 7 is a graph showing current-voltage characteristics of a TFT of Comparative Example 1 analyzed before and after exposure for the alignment treatment.

FIG. 8 is a view showing an irradiation spectrum of an alignment treatment in Example 2.

FIG. 9 is a graph showing current-voltage characteristics of a TFT of Example 2 analyzed before and after exposure for the alignment treatment.

FIG. 10 is a cross-sectional view schematically illustrating of a thin-film transistor substrate of Example 3.

FIG. 11 is a plan view schematically illustrating a pixel of the thin-film transistor substrate of Example 3.

FIG. 12 is a view showing an irradiation spectrum of an alignment treatment in Example 3.

FIG. 13 is a graph showing current-voltage characteristics of a TFT of Example 3 analyzed before and after exposure for the alignment treatment.

FIG. 14 is a view showing an irradiation spectrum of an alignment treatment in Example 4.

FIG. 15 is a graph showing current-voltage characteristics of a TFT of Example 4 analyzed before and after exposure for the alignment treatment.

### DESCRIPTION OF EMBODIMENTS

Embodiments of the present invention are described in the following. The present invention is not limited to the contents described in the following embodiments, and may be appropriately modified within a range where the configuration of the present invention is satisfied.

A liquid crystal display device of the present embodiment is a liquid crystal display device including: a thin-film transistor substrate; and a liquid crystal layer, the thin-film transistor substrate including a thin-film transistor having a channel etch structure and an alignment film, the thin-film transistor including a gate electrode, a gate insulating film, a channel layer containing an oxide semiconductor, and a pair of a source electrode and a drain electrode in the stated order, the alignment film including at least one selected from the group consisting of a cinnamate structure, a chalcone structure, an azobenzene structure, a stilbene structure, a coumarin structure, and a phenyl ester structure.

The thin-film transistor substrate includes a thin-film transistor (TFT) having a channel etch structure. The channel etch structure is provided to a TFT when a conductive film is directly stacked on a channel layer, without providing a layer protecting the channel layer (etching stopper), and a source electrode and a drain electrode are formed by dividing the conductive film by channel etching. In other words, in the channel etch structure, no etching stopper is present on the channel layer, and the source electrode and the drain electrode are present closer to the alignment film than the channel layer. In a TFT having such a channel etch structure, when the channel layer contains an oxide semiconductor, the channel layer is damaged by channel etching and therefore likely to generate a photo-leakage current in the channel layer.

The channel etch structure is advantageous to shorten the channel length. Specifically, in the channel etch structure, the distance between the source electrode and the drain electrode directly corresponds to the channel length, while in the etching stopper (ES) structure, the distance between a portion where the source electrode contacts the channel layer and a portion where the drain electrode contacts the channel layer corresponds to the channel length. Accordingly, in the case where the photolithography devices of the same resolution limit are used, the channel length is inevitably shorter in the channel etch structure. With the shorter channel length, the TFT has better drive power, so that the channel width can be also reduced.

The TFT includes a gate electrode, a gate insulating film, a channel layer containing an oxide semiconductor, and a pair of a source electrode and a drain electrode in the stated order. Namely, the TFT has a bottom gate structure. In the bottom gate structure, the gate electrode is formed prior to the channel layer, and therefore, the surface of the channel layer damaged by channel etching is not covered with the gate electrode. Accordingly, light of the photo-alignment treatment is incident on the damaged surface of the channel layer without being shielded by the gate electrode.

The oxide semiconductor may be, for example an oxide semiconductor containing oxygen and at least one of In, Ga, Zn, Al, Fe, Sn, Mg, Ca, Si, Ge, Y, Zr, La, Ce, and Hf. In particular, preferred is an oxide semiconductor containing indium, gallium, zinc, and oxygen (In—Ga—Zn—O oxide semiconductor). The In—Ga—Zn—O oxide semiconductor exhibits excellent electron mobility and realizes a thin-film transistor that is less likely to suffer a leakage current.

The TFT is preferably a pixel TFT present in a display region. In the case of a drive TFT present in a region other than the display region such as a frame region, generation of a photo-leakage current may be suppressed by shielding light of the photo-alignment treatment. By contrast, since light of the photo-alignment treatment cannot be shielded in the display region, generation of a photo-leakage current is desired to be suppressed by the use of the alignment film of the present invention.

The alignment film is arranged on the liquid crystal layer side surface of the TFT substrate and controls the alignment of liquid crystal molecules in the liquid crystal layer. When the voltage applied to the liquid crystal layer is smaller than the threshold voltage (including a case of applying no voltage), the alignment of liquid crystal molecules in the liquid crystal layer is mainly controlled by the alignment film.

In the present embodiment, the alignment film includes at least one selected from the group consisting of a cinnamate structure, a chalcone structure, an azobenzene structure, a stilbene structure, a coumarin structure, and a phenyl ester structure. These structures enable the alignment treatment with light having a wavelength of 270 nm or longer. Accordingly, the photo-alignment treatment can be performed without photoexciting the defect level of the oxide semiconductor included in the channel layer. This prevents degradation of current-voltage (I-V) characteristics of the TFT, realizing a liquid crystal display device excellent in display quality. In polymers included in the alignment film, the cinnamate structure, chalcone structure, azobenzene structure, stilbene structure, coumarin structure, and phenyl ester structure may be included in either the main chain or a side chain.

The alignment film is a photo-alignment film formed of a material showing photo-alignment properties. The material showing photo-alignment properties refers to overall materials which has a structural change by irradiation with light (electromagnetic wave) such as ultraviolet light or visible light to exhibit properties of regulating the alignment of liquid crystal molecules present therearound (alignment force) or change the level and/or direction of the alignment force.

Examples of the material showing photo-alignment properties include those including a photofunctional group that develops a reaction, such as dimerization (dimer formation), isomerization, or photo-fries rearrangement, by irradiation with light having a wavelength of 270 nm or longer. The cinnamate structure, 4-chalcone structure, coumarin structure, and stilbene structure each are a photofunctional group which develops dimerization and isomerization or a group resulting from dimerization or isomerization of the photofunctional group. The azobenzene structure is a photofunctional group which develops isomerization or a group resulting from isomerization of the photofunctional group. The phenyl ester structure is a photofunctional group which develops photo-fries rearrangement or a group resulting from photo-fries rearrangement of the photofunctional group.

The alignment film may be either a single-layer film or a film including two or more layers laminated to each other.

On the liquid crystal layer side surface of the alignment film, a polymer layer may be formed by polymer sustained alignment (PSA). In the PSA, a liquid crystal material that contains a photopolymerizable monomer (precursor) and liquid crystal molecules is sealed in a liquid crystal panel, and irradiated with light so that the photopolymerizable monomer is photopolymerized, thereby forming a polymer layer on the alignment film. The photopolymerizable monomer used is preferably, for example an acrylate monomer or a methacrylate monomer as it can be efficiently radically polymerized with light having a wavelength of 270 nm or longer. A polymer layer to be formed by polymerization of the acrylate monomer and/or methacrylate monomer includes an acrylate structure and/or a methacrylate structure.

Examples of the acrylate monomer and methacrylate monomer include monomers represented by the formula (C):

A1-(R1)ₙ-Y—(R2)ₘ-A2 (C),

wherein Y represents a structure including at least one (condensed) benzene ring in which a hydrogen atom may be substituted with a halogen atom; at least one of A1 and A2 represents acrylate or methacrylate, A1 and A2 are bonded to the (condensed) benzene ring via R1 and R2; R1 and R2 each represent a spacer, specifically, an alkyl chain having a carbon number of 10 or smaller in which a methylene group may be substituted with a functional group selected from ester, ether, amide, and ketone groups, and a hydrogen atom may be substituted with a halogen atom; n and m are each 0 or 1, and no spacer is provided when n and m both represent 0.

The skeleton Y in the formula (C) is preferably a structure represented by the formula (C-1), (C-2), or (C-3). Hydrogen atoms in the formulae (C-1), (C-2), and (C-3) may be each independently substituted with a halogen atom, a methyl group, or an ethyl group.

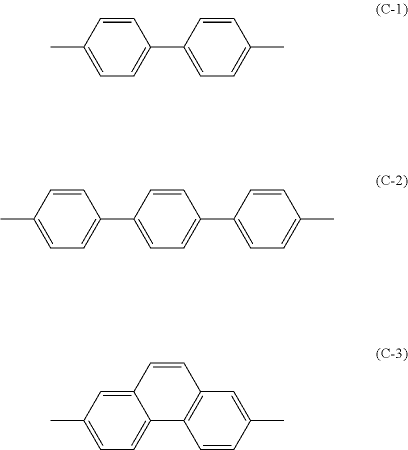

Specific examples of the monomer represented by the formula (C) include those represented by the formulae (C-1-1), (C-1-2), and (C-3-1).

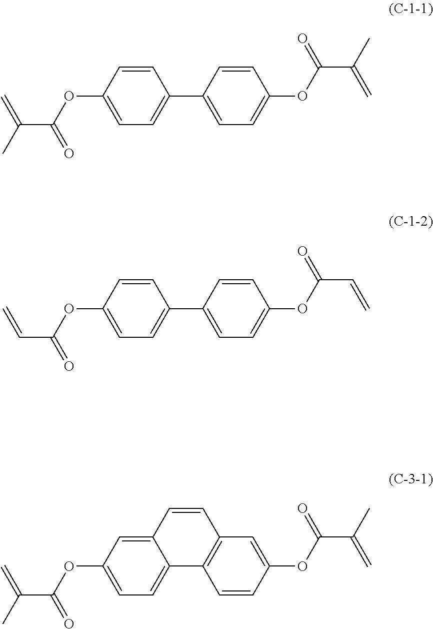

The pretilt angle (angle formed between the surface of the alignment film and the major axis of the liquid crystal molecules) of the liquid crystal molecules provided by the alignment film (or the alignment film and the polymer layer) is not particularly limited. The alignment film may be either a horizontal alignment film or a vertical alignment film. In the case of the horizontal alignment film used for a transverse electric field mode such as an IPS mode and an FFS mode, the pre-tilt angle is preferably substantially 0° (for example, smaller than 10°), more preferably 0°. In the case of the horizontal alignment film used for a vertical electric field mode such as a TN mode and an STN mode, the pre-tilt angle is preferably 0.5° or larger and smaller than 25°, more preferably 1° or larger and smaller than 10°.

The liquid crystal layer may be one commonly used in a liquid crystal display device in which the initial alignment of the liquid crystal is controlled by an alignment film. The anisotropy of dielectric constant (Δ∈) defined by the formula (P) of the liquid crystal molecules contained in the liquid crystal layer may be either negative or positive. In other words, the liquid crystal molecules may have either negative anisotropy of dielectric constant or positive anisotropy of dielectric constant. The liquid crystal molecules having negative anisotropy of dielectric constant used may have Δ∈ of, for example, −1 to −20. The liquid crystal molecules having positive anisotropy of dielectric constant used may have Δ∈ of, for example, 1 to 20.

Δ∈=(Dielectric constant in the major axis direction)−(Dielectric constant in the minor axis direction) (P)

The display mode of the liquid crystal display device of the present embodiment is not particularly limited, and may be, for example, a horizontal alignment mode such as a fringe field switching (FFS) mode or an in-plane switching (IPS) mode; a vertical alignment mode such as a vertical alignment twisted nematic (VATN) mode, a multi-domain vertical alignment (MVA) mode, or a patterned vertical alignment (PVA) mode; or a twisted nematic (TN) mode.

In the horizontal alignment mode, the thin-film transistor substrate is provided with a pair of electrodes configured to apply an electric field to the liquid crystal layer. In the FFS mode, the thin-film transistor substrate is provided with a structure (FFS electrode structure) including a planar electrode, a slit electrode, and an insulating film placed between the planar electrode and the slit electrode, and an oblique electric field (fringe electric field) is created in the liquid crystal layer adjacent to the thin-film transistor substrate. Normally, the slit electrode, the insulating film, and the planar electrode are arranged in the stated order from the liquid crystal layer side. The slit electrode may be, for example, an electrode provided with, as a slit, a linear aperture with its whole circumference surrounded by the electrode or a comb-shaped electrode in which multiple teeth portions are provided and linear cut portions between the teeth portions form slits.

In the IPS mode, the thin-film transistor substrate is provided with a pair of comb-shaped electrodes and a transverse electric field is created in the liquid crystal layer adjacent to the thin-film transistor substrate. The pair of comb-shaped electrodes may be, for example, a pair of electrodes each provided with multiple teeth portions, arranged in such a manner that the teeth portions mesh with each other.

In a VATN-mode liquid crystal display device, alignment treatment is performed in multiple directions to each pixel, and therefore, the alignment treatment with light is suitably employed. In such a VATN-mode liquid crystal display device too, the effect of preventing degradation of TFT characteristics can be achieved according to the present invention.

The liquid crystal display device of the present embodiment may include, in addition to the thin-film transistor substrate and the liquid crystal layer, members such as a color filter substrate; a polarizing plate; a backlight; an optical film such as a phase difference film, a viewing angle expansion film, or a brightness enhancement film; an external circuit such as a tape carrier package (TCP) or a printed circuit board (PCB); and a bezel (frame). These members are not particularly limited, and those commonly used in the field of liquid crystal display devices may be used. Therefore, descriptions thereof are omitted.

Next, a description is given on a method for producing the liquid crystal display device of the present embodiment. The method for producing the liquid crystal display device of the present embodiment is a method for producing a liquid crystal display device including a thin-film transistor substrate that includes a bottom gate type thin-film transistor and an alignment film, and a liquid crystal layer, including: step (A) of forming a gate electrode; step (B) of forming a gate insulating film; step (C) of forming a channel layer containing an oxide semiconductor; step (D) of forming a pair of a source electrode and a drain electrode by forming a metal film on the gate insulating film and on the channel layer and partly removing the metal film formed on the channel layer by etching; and step (E) of forming the alignment film that includes at least one selected from the group consisting of a cinnamate structure, a chalcone structure, an azobenzene structure, a stilbene structure, a coumarin structure, and a phenyl ester structure, the step (E) including irradiation with light having a wavelength of 270 nm or longer.

In the step (A) of forming a gate electrode, for example, a metal film is formed by sputtering or the like, and the formed film is patterned as desired by photolithography. The metal film may be either a single-layer film or a film including two or more layers laminated to each other. Examples of the material of the metal film include high-melting-point metals such as tungsten, molybdenum, tantalum, and titanium and nitrides of high-melting-point metals.

In the step (B) of forming a gate insulating film, for example, an insulating material is formed into a film by sputtering, ordinary-pressure CVD, low-pressure CVD, plasma CVD, remote plasma CVD, or the like. Examples of the insulating material include silicon dioxide (SiO₂), silicon nitride (SiNx), tantalum oxide, and aluminum oxide.

In the step (C) of forming a channel layer, for example, an oxide semiconductor is formed into a film by sputtering or the like, and the formed film was patterned as desired by photolithography.

In the first stage of the step (D) of forming a pair of a source electrode and a drain electrode, for example, a metal film is formed on the gate insulating film and the channel layer by sputtering or the like. The metal film may be either a single-layer film or a film including two or more layers laminated to each other. Examples of the material of the metal film include metals such as titanium, chromium, aluminum, and molybdenum, and alloys of these. In the second stage of the step (D), for example, channel etching is performed by photolithography to form a pair of a source electrode and a drain electrode. Specifically, treatment is performed in the order of application of a resist, pre-baking, exposure, development, post-baking, dry etching, and resist stripping, thereby patterning the metal film.

In the step (E) of forming an alignment film, for example, treatment is performed in the order of application of an alignment agent containing a material that shows photo-alignment properties, pre-baking, exposure for alignment treatment, and post-baking, or in the order of application of an alignment agent containing a material that shows photo-alignment properties, pre-baking, post-baking, and exposure for alignment treatment. In the exposure for alignment treatment, polarized light or non-polarized light having a wavelength of 270 nm or longer is used.

As above, the use of light having a wavelength of 270 nm or longer in the step (E) can prevent photoexcitation of the defect level of the oxide semiconductor included in the channel layer of the TFT. This can prevent degradation of current-voltage (I-V) characteristics of the TFT, leading to production of a liquid crystal display device excellent in display quality.

In the case of forming a polymer layer on the alignment film by PSA, after sealing of a liquid crystal material that includes a photopolymerizable monomer (precursor) and liquid crystal molecules in a liquid crystal panel, the liquid crystal material is irradiated with polarized light or non-polarized light having a wavelength of 270 nm or longer for photopolymerization of the photopolymerizable monomer. In this process, the liquid crystal material is irradiated with light from the TFT substrate side. This is because, if irradiation with light is performed from the color filter substrate side, the light is absorbed by the color filter. The polymer prepared by photopolymerization has lower solubility into the liquid crystal material than the photopolymerizable monomer, and therefore is formed into a film on the thin-film transistor substrate, thereby forming a polymer layer.

The photopolymerizable monomer is preferably an acrylate monomer or a methacrylate monomer as it is efficiently radically polymerized with light having a wavelength of 270 nm or longer. The liquid crystal material may optionally contain a polymerization initiator. The polymerization initiator preferably has a photosensitive wavelength of 270 nm or longer.

The polymer layer formed by PSA may be either a film covering the entire surface of the alignment film or a film dispersively formed on the alignment film.

Here, each and every detail described for the above embodiment of the present invention shall be applied to all the aspects of the present invention.

The present invention is more specifically described in the following based on examples and comparative examples with reference to drawings. The examples, however, are not intended to limit the present invention.

### Example 1

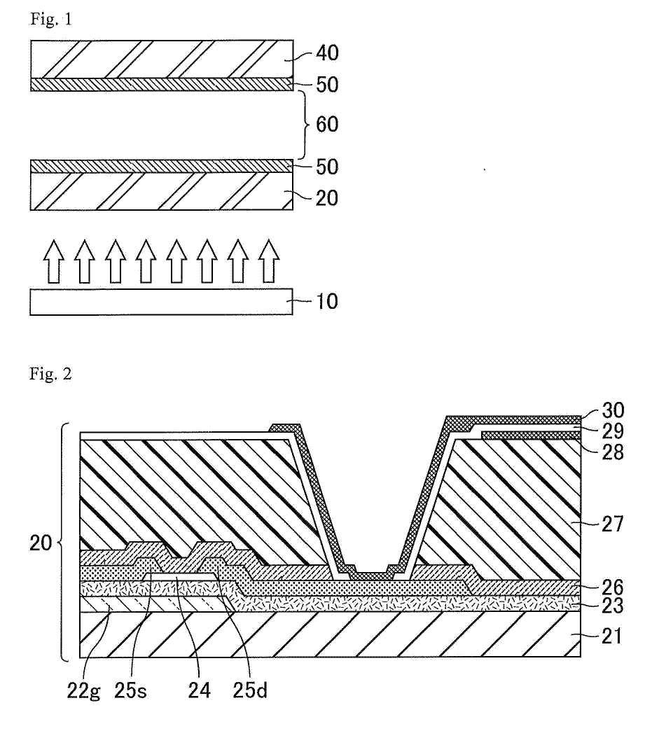

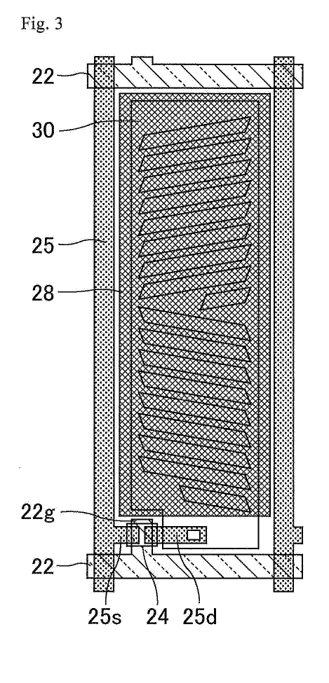

Example 1 relates to a liquid crystal display device of the fringe field switching (FFS) mode that is a horizontal alignment mode. FIG. 1 is a cross-sectional view schematically illustrating a structure of a liquid crystal display device of Example 1. FIG. 2 is a cross-sectional view schematically illustrating a thin-film transistor substrate of Example 1. FIG. 3 is a plan view schematically illustrating a pixel of the thin-film transistor substrate of Example 1.

As illustrated in FIG. 1, the liquid crystal display device of Example 1 included, from the back side toward the viewer side, a backlight 10, a thin-film transistor (TFT) substrate 20, an alignment film 50, a liquid crystal layer 60, an alignment film 50, and a color filter (CF) substrate 40 in the stated order. Void arrows in FIG. 1 schematically indicate the travel direction of light emitted from the backlight 10.

As illustrated in FIG. 2, the TFT substrate 20 had a channel etch (CE) structure. Specifically, on the substrate 21, a gate electrode 22g that was a laminate (W/TaN) of a tungsten film with a thickness of 300 nm and a tantalum nitride film with a thickness of 20 nm was provided in a predetermined pattern. As illustrated in FIG. 3, the gate electrode 22g was branched from the gate line 22.

On the gate electrode 22g was provided a gate insulating film 23 that was a laminate (SiO₂/SiNₓ) of a silicon oxide film with a thickness of 50 nm and a silicon nitride film with a thickness of 300 nm to cover the entire surface of the substrate.

On the gate insulating film 23 was provided a channel layer 24 including an oxide semiconductor with a thickness of 50 nm. The oxide semiconductor used contained indium, gallium, zinc, and oxygen (In—Ga—Zn—O oxide semiconductor). The channel layer 24 was formed by forming the oxide semiconductor into a film by sputtering and patterning the formed film as desired by photolithography including a wet etching step and a resist stripping step.

On the channel layer 24 were provided a source electrode 25s and a drain electrode 25d each of which was a laminate (Ti/Al/Ti) including a titanium film with a thickness of 100 nm, an aluminum film with a thickness of 300 nm, and a titanium film with a thickness of 30 nm, in a predetermined pattern. As illustrated in FIG. 3, the source electrode 25s was branched from the source line 25, and the drain electrode 25d was placed to oppose the source electrode 25s across the channel layer 24. The source electrode 25s and the drain electrode 25d were formed by forming the laminate on the entire surface of the substrate 21 by sputtering and then patterning the laminated film by photolithography including a dry etching step (channel etching) and a resist stripping step. In the dry etching step, the laminate formed on the channel layer 24 was partly removed to have a predetermined channel length (L=6 m) and channel width (W=20 m). Plasma generated in the dry etching step gives damage to the channel layer 24 including an oxide semiconductor exposed when the laminate was removed.

On the source electrode 25s and the drain electrode 25d was provided a channel protection film 26 that was a silicon oxide film (SiO₂) with a thickness of 300 nm to cover the entire surfaces of the substrates. An acrylic resin film 27 with a thickness of 2.0 μm was further provided to cover the entire surfaces of the substrates.

Since the liquid crystal display device of the present example is of the FFS mode, an auxiliary capacitance electrode 28 that was an indium-zinc-oxygen film (IZO) with a thickness of 100 nm was provided in a predetermined pattern on the acrylic resin film 27. An aperture penetrating the channel protection film 26 and the acrylic resin film 27 was further formed to partly expose the drain electrode 25d.

Subsequently, an auxiliary capacitance insulating film 29 that was a silicon nitride (SiNₓ) film with a thickness of 100 nm was provided except for the region where the drain electrode 25d was partly exposed. Further, a pixel electrode 30 that was an indium-zinc-oxygen (IZO) film with a thickness of 100 nm was provided in a predetermined pattern. As described above, a TFT substrate having the structure as illustrated in FIG. 2 and FIG. 3 was produced.

Though not illustrated in FIG. 2, an alignment film 50 was provided on the pixel electrode 30. The alignment film 50 was also formed on the surface of the CF substrate 40 on the side adjacent to the liquid crystal layer 60.

The alignment films 50 were formed by the following procedure. First, an alignment agent containing, as a solid content, a polyimide polymer that included an azobenzene structure in the main chain was applied to the TFT substrate 20. The alignment agent had a composition of N-methyl-2-pyrrolidone (NMP):butyl cellosolve (BC):solid content=66:30:4 (weight ratio). The same alignment agent was also applied to the CF substrate 40.

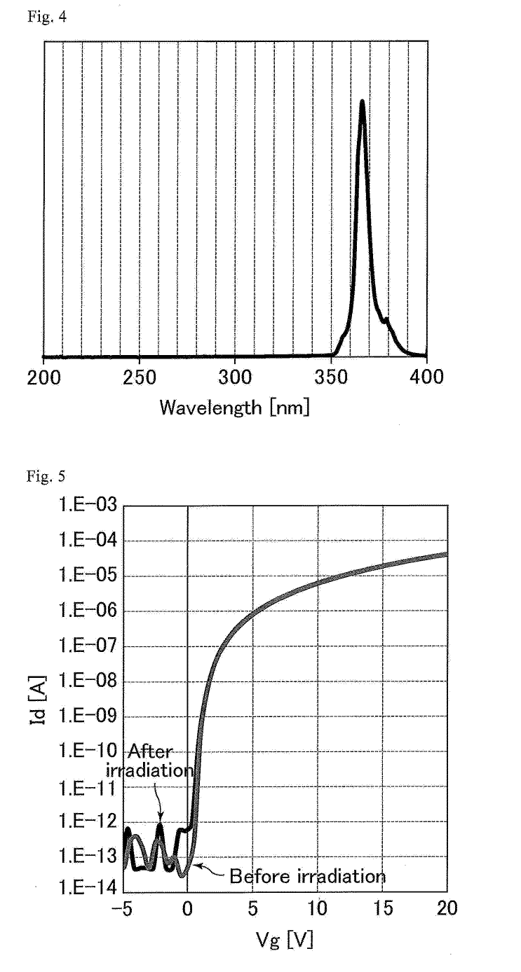

The TFT substrate 20 and the CF substrate 40 each with the alignment agent applied thereto were pre-baked at 70° C. for two minutes. The alignment films 50 formed by the pre-baking each had a thickness of 100 nm. After the pre-baking, irradiation with polarized ultraviolet rays in the normal direction of the substrate was performed as exposure for alignment treatment. FIG. 4 is a view showing an irradiation spectrum of the alignment treatment in Example 1. The light source of the polarized ultraviolet rays used was a high-intensity point light source (produced by Ushio Inc., trade name: Deep UV lamp). Further, a bandpass filter that passes light with a wavelength of 365 nm was used. The polarized ultraviolet rays with which the alignment films 50 were irradiated had an intensity measured with an accumulated UV meter (produced by Ushio Inc., trade name: UIT-250, photodetector type: UVD-S365) of 1 J/cm². After the exposure for alignment treatment, the alignment films 50 were post-baked at 110° C. for 30 minutes and then at 230° C. for 30 minutes.

Next, a predetermined pattern was drawn with a sealing agent (produced by Kyoritsu Chemical & Co., Ltd., trade name: WORLD ROCK) on the CF substrate 40. Then, a liquid crystal was dropped to the TFT substrate 20 by one drop filling (ODF). The liquid crystal used was MLC6610 produced by Merck KGaA. The CF substrate 40 and the TFT substrate 20 were attached to each other in such a manner that the polarization axes of the polarized ultraviolet rays in the alignment treatment coincided with each other, and the liquid crystal was sealed in between the TFT substrate 20 and the CF substrate 40. The heat treatment was then carried out at 130° C. for 40 minutes. The formed liquid crystal layer 60 had a d·Δn (product of the thickness d and the refractive index anisotropy Δn) of 330 nm. A pair of polarizing plates was attached to the back side of the TFT substrate 20 and the viewing surface side of the CF substrate 40 in such a manner that the polarization axes were in a relation of crossed Nicols. Further, the backlight 10 equipped with a light emitting diode (LED) was mounted on the back side of the TFT substrate 20, thereby completing the FFS-mode liquid crystal display device of Example 1.

### <Characteristics Evaluation of Example 1>

### 1) Current-Voltage (I-V) Characteristics of TFT

The I-V characteristics of the TFT of Example 1 were analyzed before and after the exposure for alignment treatment using a semiconductor parameter analyzer 4156C produced by Agilent Technologies. In the analysis, the voltage between the source electrode 25s and the drain electrode 25d was set to 10 V (Vds=10 V), and the amount of the current (Id) flowing in the channel layer 24 upon change of the voltage (Vg) of the gate electrode 22g was measured. FIG. 5 is a graph showing the current-voltage characteristics of the TFT of Example 1 analyzed before and after the exposure for alignment treatment. As shown in FIG. 5, the I-V characteristics were hardly changed before and after the exposure for alignment treatment. Specifically, the threshold voltage of the TFT was lowered by 0.04 V (ΔVth=−0.04 V) after the exposure.

### 2) Display Unevenness a Gray Scale Value of 31

The screen lit at the gray scale value of 31 was visually observed to evaluate the display unevenness. The gray scale value of 31 corresponds to the rising portion of the voltage-transmittance curve (V-T line) and shows a steep change of the transmittance against the voltage change, so that the display unevenness tends to be significant. As a result of the observation, the liquid crystal display device of Example 1 had favorable display quality without display unevenness. Accordingly, it was confirmed that nonuniform DC charging due to the TFT characteristics did not occur.

### Comparative Example 1

An FFS-mode liquid crystal display device was produced in the same manner, except for the formation of the alignment film, as in Example 1.

The alignment film was formed by the following procedure. First, an alignment agent containing, as a solid content, a polyimide polymer that included a cyclobutane structure in the main chain was applied to the TFT substrate. The alignment agent had a composition of NMP:BC:solid content=66:30:4 (weight ratio). The same alignment agent was also applied to the CF substrate.

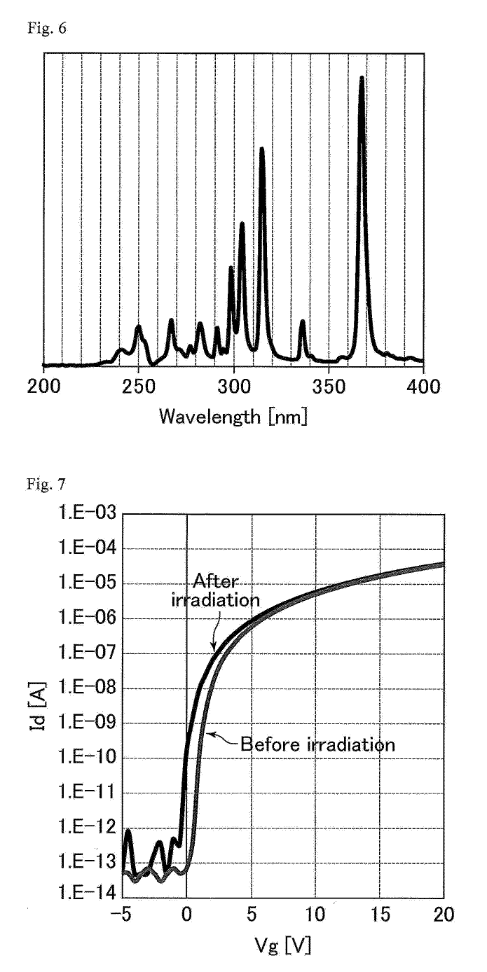

The TFT substrate and the CF substrate each with the alignment agent applied thereto were pre-baked at 70° C. for two minutes. The alignment films formed by the pre-baking each had a thickness of 100 nm. After the pre-baking, the alignment films were post-baked at 230° C. for 30 minutes. After the post-baking, irradiation with polarized ultraviolet rays in the normal direction of the substrate was performed as exposure for alignment treatment. FIG. 6 is a view showing the irradiation spectrum of the alignment treatment in Comparative Example 1. The light source of the polarized ultraviolet rays used was a high-intensity point light source (produced by Ushio Inc., trade name: Deep UV lamp). No bandpass filter was used. The polarized ultraviolet rays with which the alignment films were irradiated had an intensity measured with an accumulated UV meter (produced by Ushio Inc., trade name: UIT-250, photodetector type: UVD-S254) of 0.6 J/cm². After the exposure for alignment treatment, the alignment films were additionally baked at 230° C. for 30 minutes.

### <Characteristics Evaluation of Comparative Example 1>

### 1) Current-Voltage (I-V) Characteristics of TFT

The I-V characteristics of the TFT of Comparative Example 1 were analyzed before and after the exposure for alignment treatment in the same manner as in Example 1. FIG. 7 is a graph showing the current-voltage characteristics of the TFT of Comparative Example 1 analyzed before and after the exposure for alignment treatment. As shown in FIG. 7, the I-V characteristics were obviously changed before and after the exposure for alignment treatment. Specifically, the threshold voltage of the TFT was lowered by 0.89 V (ΔVth=−0.89 V) after the exposure.

### 2) Display Unevenness at a Gray Scale Value of 31

The screen lit at the gray scale value of 31 was visually observed to evaluate the display unevenness. As a result of the observation, the liquid crystal display device of Comparative Example 1 had display unevenness even through a neutral density filter (ND10 filter) that passes 10% of the light. Namely, the liquid crystal display device of Comparative Example 1 did not have enough display quality. The display unevenness is presumably caused by nonuniform DC charging due to the TFT characteristics.

3) Consideration about the Evaluation Results

The TFT of Comparative Example 1 had its threshold voltage significantly lowered by the exposure for alignment treatment, resulting in display unevenness. The spectrum of the light used for the alignment treatment in Comparative Example 1 was different from that of Example 1 in that it markedly included ultraviolet rays having a short wavelength of 350 nm or shorter. This indicates that the short-wavelength ultraviolet rays affected the characteristics of the oxide semiconductor (In—Ga—Zn—O) included in the channel layer of the TFT. In the case of the TFT of the channel etch (CE) structure, the surface of the channel layer (back channel) is exposed during the dry etching process for separating the source electrode and the drain electrode to be damaged by plasma discharge. This damage creates a defect level in the channel layer which mainly generates electron-hole pairs when irradiated with light. As a result, the I-V characteristics of the TFT are presumably negatively shifted.

In Example 1, since irradiation with ultraviolet rays of 350 nm or longer was performed, the defect level was not photoexcited, so that generation of electron-hole pairs was presumably suppressed.

### Example 2

An FFS-mode liquid crystal display device was produced in the same manner, except for the formation of the alignment film, as in Example 1.

The alignment film was formed by the following procedure. First, an alignment agent containing, as a solid content, a polyimide polymer that included a cinnamate structure in the main chain was applied to the TFT substrate. The alignment agent had a composition of NMP:BC:solid content=66:30:4 (weight ratio). The same alignment agent was also applied to the CF substrate.

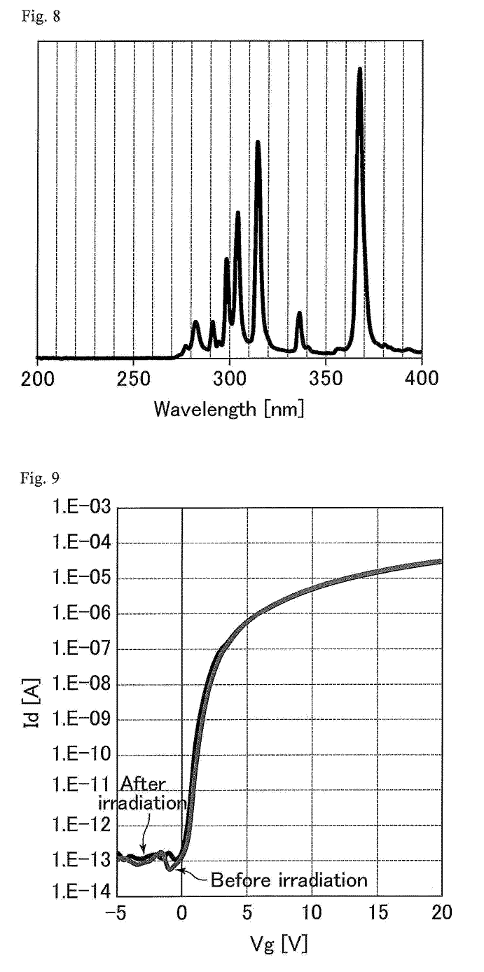

The TFT substrate and the CF substrate each with the alignment agent applied thereto were pre-baked at 70° C. for two minutes. The alignment films formed by the pre-baking each had a thickness of 100 nm. After the pre-baking, irradiation with polarized ultraviolet rays in the normal direction of the substrate was performed as exposure for alignment treatment. FIG. 8 is a view showing an irradiation spectrum of the alignment treatment in Example 2. The light source of the polarized ultraviolet rays used was a high-intensity point light source (produced by Ushio Inc., trade name: Deep UV lamp). Further, a shortcut filter that blocks light having a wavelength of 270 nm or shorter was used. The polarized ultraviolet rays with which the alignment films were irradiated had a strength measured with an accumulated UV meter (produced by Ushio Inc., trade name: UIT-250, photodetector type: UVD-S313) of 1 J/cm². After the exposure for alignment treatment, the alignment films were post-baked at 230° C. for 30 minutes.

### <Characteristics Evaluation of Example 2>

### 1) Current-Voltage (I-V) Characteristics of TFT

The I-V characteristics of the TFT of Example 2 were analyzed before and after the exposure for alignment treatment in the same manner as in Example 1. FIG. 9 is a graph showing the current-voltage characteristics of the TFT of Example 2 analyzed before and after the exposure for alignment treatment. As shown in FIG. 9, the I-V characteristics were slightly changed before and after the exposure for alignment treatment. Specifically, the threshold voltage of the TFT was lowered by 0.24 V (ΔVth=−0.24 V) after the exposure.

### 2) Display Unevenness at a Gray Scale Value of 31

The screen lit at the gray scale value of 31 was visually observed to evaluate the display unevenness. As a result of the observation, the liquid crystal display device of Example 2 had favorable display quality without display unevenness (nonuniform DC charging due to TFT characteristics) through a neutral density filter (ND2 filter) that passes 50% of light.

3) Consideration about the Evaluation Results

In the case of the TFT of Example 2, not like the TFT of Comparative Example 1, the threshold voltage was only slightly lowered by the exposure for alignment treatment. The spectrum of the light used for the alignment treatment in Example 2 was different from that of Comparative Example 1 in that it did not include ultraviolet rays having a short wavelength of 270 nm or shorter. This indicates that the defect level of the oxide semiconductor (In—Ga—Zn—O) that shifts the I-V characteristics is excited by light having a wavelength of shorter than 270 nm.

### Example 3

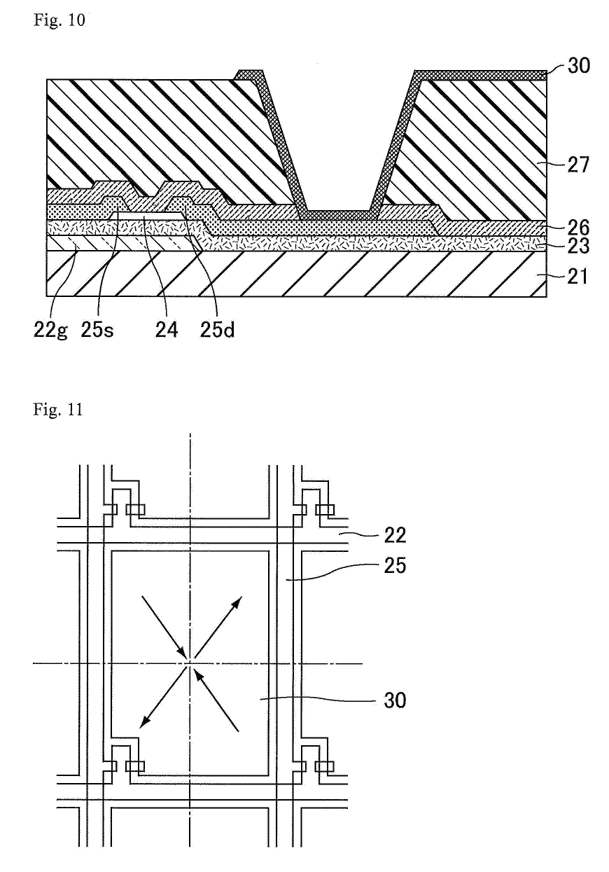

Example 3 relates to a liquid crystal display device of the vertical alignment twisted nematic (VATN) mode that is a vertical alignment mode. FIG. 10 is a cross-sectional view schematically illustrating a thin-film transistor substrate of Example 3. FIG. 11 is a plan view schematically illustrating a pixel of the thin-film transistor substrate of Example 3. The liquid crystal display device of Example 3 also had a structure illustrated in FIG. 1.

The thin-film transistor substrate (TFT substrate) 20 of Example 3 had a cross-sectional structure different from that of the TFT substrate 20 of Example 1 in that it had a channel etch (CE) structure as illustrated in FIG. 10 and included no auxiliary capacitance electrode 28 or auxiliary capacitance insulating film 29.

Though not illustrated in FIG. 10, the alignment film 50 was provided on the pixel electrode 30. The alignment film 50 was also formed on the surface of the color filter substrate (CF substrate) 40 on the side adjacent to the liquid crystal layer 60.

The alignment films 50 were formed by the following procedure. First, an alignment agent containing, as a solid content, a polyimide polymer that included a cinnamate structure and an alkyl fluoride chain in a side chain was applied to the TFT substrate. The alignment agent had a composition of N-methyl-2-pyrrolidone (NMP):butyl cellosolve (BC):solid content=66:30:4 (weight ratio). The same alignment agent was also applied to the CF substrate 40.

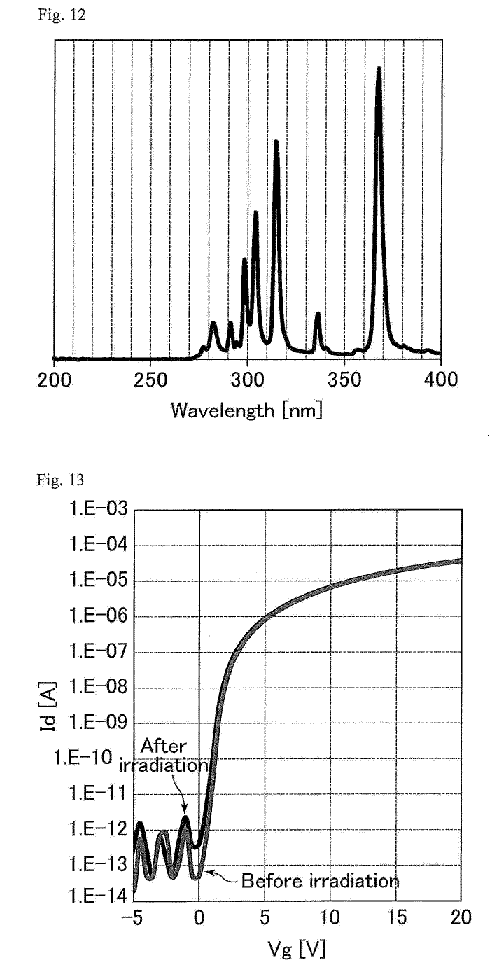

The TFT substrate 20 and the CF substrate 40 each with the alignment agent applied thereto were pre-baked at 70° C. for two minutes. The alignment films 50 formed by the pre-baking each had a thickness of 100 nm. After the pre-baking, the alignment films 50 were post-baked at 200° C. for 30 minutes. After the post-baking, irradiation with p-polarized ultraviolet rays in a direction inclined at 400 relative to the normal direction of the substrate was performed as exposure for alignment treatment. FIG. 12 is a view showing an irradiation spectrum of the alignment treatment in Example 3. The light source of the p-polarized ultraviolet rays used was a high-intensity point light source (produced by Ushio Inc., trade name: Deep UV lamp). Further, a shortcut filter that blocks light with a wavelength of 270 nm or shorter was used. The p-polarized ultraviolet rays with which the alignment films 50 were irradiated had an intensity measured with an accumulated UV meter (produced by Ushio Inc., trade name: UIT-250, photodetector type: UVD-S313) of 40 mJ/cm².

Next, a predetermined pattern was drawn with a sealing agent (produced by Kyoritsu Chemical & Co., Ltd., trade name: WORLD ROCK) on the CF substrate 40. Then, a liquid crystal was dropped to the TFT substrate 20 by one drop filling (ODF). The liquid crystal used was MLC6610 produced by Merck KGaA. The CF substrate 40 and the TFT substrate 20 were attached to each other in such a manner that the pretilt azimuths thereof were perpendicular to each other, and the liquid crystal was sealed in between the TFT substrate 20 and the CF substrate 40. This formed four domains different in the alignment direction of the liquid crystal molecules in each pixel. Arrows in FIG. 11 indicate the alignment directions of the liquid crystal molecules in the respective domains. The heat treatment was then carried out at 130° C. for 40 minutes. The formed liquid crystal layer 60 had a d·Δn (product of the thickness d and the refractive index anisotropy Δn) of 340 nm. A pair of polarizing plates was attached to the back side of the TFT substrate 20 and the viewing surface side of the CF substrate 40 in such a manner that the polarization axes were in a relation of crossed Nicols. Further, the backlight 10 equipped with an LED was mounted on the back side of the TFT substrate 20, thereby completing the VATN-mode liquid crystal display device of Example 3.

### <Characteristics Evaluation of Example 3>

### 1) Current-Voltage (I-V) Characteristics of TFT

The I-V characteristics of the TFT of Example 3 were analyzed before and after the exposure for alignment treatment in the same manner as in Example 1. FIG. 13 is a graph showing the current-voltage characteristics of the TFT of Example 3 analyzed before and after the exposure for alignment treatment. As shown in FIG. 13, the I-V characteristics were slightly changed before and after the exposure for alignment treatment. Specifically, the threshold voltage of the TFT was lowered by 0.18 V (ΔVth=−0.18 V) after the exposure.

### 2) Display Unevenness at a Gray Scale Value of 31

The screen lit at the gray scale value of 31 was visually observed to evaluate the display unevenness. As a result of the observation, the liquid crystal display device of Example 3 had favorable display quality without display unevenness (nonuniform DC charging due to TFT characteristics) through a neutral density filter (ND2 filter) that passes 50% of light.

As described above, the effects of the present invention were confirmed not only in the case where the alignment mode of the liquid crystal was the horizontal alignment mode (transverse electric field mode) as in Examples 1 and 2 but also in the case where the alignment mode was the VATN mode.

### Example 4

Example 4 relates to a liquid crystal display device of the multi-domain vertical alignment (MVA) mode that is a vertical alignment mode characterized by polymer sustained alignment (PSA).

The TFT substrate of Example 4 had a CE structure shown in FIG. 10 and had the same cross-sectional structure as that of the TFT substrate of Example 3. The TFT substrate of Example 4, however, had a plan structure different from that of the TFT substrate of Example 3 in that an electrode slit was formed in the pixel electrode.

Also in Example 4, the alignment film was formed on the pixel electrode of the TFT substrate. The alignment film was also formed on the surface of the CF substrate on the side adjacent to the liquid crystal layer.

The alignment films were formed by the following procedure. First, an alignment agent containing, as a solid content, a polyimide polymer that included a cholestane structure and a cinnamate structure in the side chain was applied to the TFT substrate. The alignment agent had a composition of NMP:BC:solid content=66:30:4 (weight ratio). The same alignment agent was also applied to the CF substrate.

The TFT substrate and the CF substrate each with the alignment agent applied thereto were pre-baked at 70° C. for two minutes. The alignment films formed by the pre-baking each had a thickness of 100 nm. After the pre-baking, the alignment films were post-baked at 200° C. for 30 minutes.

Next, a predetermined pattern was drawn with a sealing agent (produced by Kyoritsu Chemical & Co., Ltd., trade name: WORLD ROCK) on the CF substrate. Then, a liquid crystal was dropped to the TFT substrate 20 by one drop filling (ODF). The liquid crystal used was MLC6610 (Merck KGaA) blended with, as a precursor of a methacrylate polymer layer, 0.3 wt % of biphenyl-4,4′-diyl bis(2-methylacrylate). The CF substrate and the TFT substrate were attached to each other, and the liquid crystal was sealed in between the substrates. The heat treatment was then carried out at 130° C. for 40 minutes. The formed liquid crystal layer had a d·Δn (product of the thickness d and the refractive index anisotropy Δn) of 340 nm.

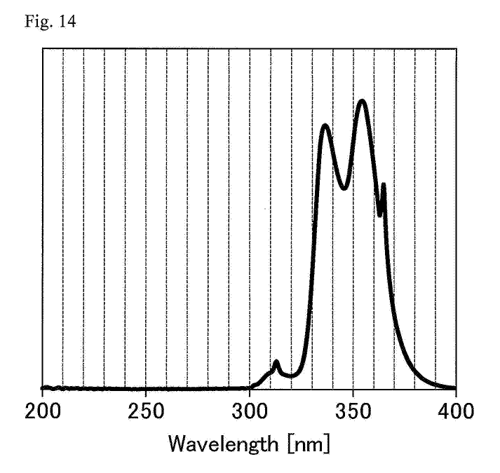

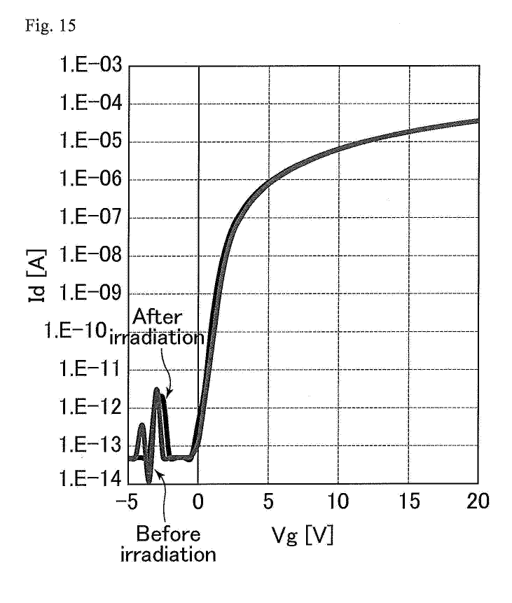

Next, irradiation with non-polarized ultraviolet rays in the normal direction of the substrate was performed as the exposure for alignment treatment, while a direct current (DC) voltage of 20 V was applied between the pixel electrode provided in the TFT substrate and the common electrode provided in the CF substrate. FIG. 14 is a view showing an irradiation spectrum of the alignment treatment in Example 4. The light source of the non-polarized ultraviolet rays used was a black light fluorescent lamp (produced by Toshiba Corporation, trade name: FHF32BLB). No cut-off filter was used. The non-polarized ultraviolet rays had an intensity measured with an accumulated UV meter (produced by Ushio Inc., trade name: UIT-250, photodetector type: UVD-S365) of 5 J/cm². The irradiation with non-polarized ultraviolet rays photopolymerized biphenyl-4,4′-diyl bis(2-methylacrylate) in the liquid crystal, thereby forming a methacrylate polymer layer on the alignment films.

A pair of polarizing plates was attached to the back side of the TFT substrate and the viewing surface side of the CF substrate in such a manner that the polarization axes were in a relation of crossed Nicols. Further, an LED backlight was mounted on the back side of the TFT substrate, thereby completing the MVA-mode liquid crystal display device of Example 4 to which the PSA technique was applied.

### <Characteristics Evaluation of Example 4>

### 1) Current-Voltage (I-V) Characteristics of TFT

The I-V characteristics of the TFT of Example 4 were analyzed before and after the exposure for alignment treatment in the same manner as in Example 1. FIG. 15 is a graph showing the current-voltage characteristics of the TFT of Example 4 analyzed before and after the exposure for alignment treatment. As shown in FIG. 15, the I-V characteristics were slightly changed before and after the exposure for alignment treatment. Specifically, the threshold voltage of the TFT was lowered by 0.25 V (ΔVth=−0.25 V) after the exposure.

### 2) Display Unevenness at a Gray Scale Value of 31

The screen lit at the gray scale value of 31 was visually observed to evaluate the display unevenness. As a result of the observation, the liquid crystal display device of Example 4 had favorable display quality without display unevenness (nonuniform DC charging due to TFT characteristics) through a neutral density filter (ND2 filter) that passes 50% of light.

As described above, the effects of the present invention was confirmed also in the case where the PSA technique was used in combination.

Technical features mentioned in the examples of the present invention may be combined with each other to provide another embodiment of the present invention.

### [Additional Remarks]

An aspect of the present invention may be a liquid crystal display device including a thin-film transistor substrate and a liquid crystal layer, the thin-film transistor substrate including a thin-film transistor having a channel etch structure and an alignment film, the thin-film transistor including a gate electrode, a gate insulating film, a channel layer containing an oxide semiconductor, and a pair of a source electrode and a drain electrode in the stated order, the alignment film including at least one selected from the group consisting of a cinnamate structure, a chalcone structure, an azobenzene structure, a stilbene structure, a coumarin structure, and a phenyl ester structure. According to the aspect, since the photofunctional group contained in the alignment film is a group which enables the alignment treatment with light having a wavelength of 270 nm or longer, the photo-alignment treatment can be performed without allowing photoexcitation of the defect level of the oxide semiconductor included in the channel layer in the thin-film transistor having a channel etch structure. Degradation of the current-voltage (I-V) characteristics of the TFT due to the photo-alignment treatment can be thus prevented. This can prevent the nonuniform DC charging due to the TFT characteristics, realizing a liquid crystal display device excellent in the display quality.

The oxide semiconductor preferably contains indium, gallium, zinc, and oxygen. Such an oxide semiconductor exhibits excellent electron mobility and realizes a thin-film transistor that is less likely to suffer a leakage current. Accordingly, the use of the oxide semiconductor having such excellent TFT characteristics and the photofunctional group in combination can provide a significant effect of preventing degradation of the current-voltage (I-V) characteristics of the TFT.

A polymer layer including at least one of the acrylate structure and the methacrylate structure may be provided between the alignment film and the liquid crystal layer. Such a polymer layer can be produced by PSA. The polymer layer is preferred as it can be formed by efficiently radically polymerizing a precursor (e.g., monomer) contained in the liquid crystal with light having a wavelength of 270 nm or longer.

The thin-film transistor substrate may have a pair of electrodes configured to apply an electric field to the liquid crystal layer. With such a configuration, the present invention can be applied to a liquid crystal display device of a horizontal alignment mode such as an in-plane switching (IPS) mode or a fringe field switching (FFS) mode. In the IPS mode, a pair of comb-shaped electrodes arranged on the same insulating film is suitably used as the pair of electrodes, and a transverse electric field is created in the liquid crystal layer. In the FFS mode, a combination of an electrode with a slit arranged in a layer above the insulating film and a planar electrode arranged in a layer below the insulating film is suitably used as the pair of electrodes, and an oblique electric field is created in the liquid crystal layer.

The display mode of the liquid crystal display device may be a vertical alignment twisted nematic (VATN) mode. In the VATN-mode liquid crystal display device, alignment treatment is performed in multiple directions to each pixel, and therefore, the alignment treatment with light is suitably employed. In such a VATN-mode liquid crystal display device too, the effect of preventing degradation of the TFT characteristics can be achieved according to the present invention.

Another aspect of the present invention may be a method for producing a liquid crystal display device including a thin-film transistor substrate that includes a bottom gate type thin-film transistor and an alignment film, and a liquid crystal layer, including: step (A) of forming a gate electrode; step (B) of forming a gate insulating film; step (C) of forming a channel layer containing an oxide semiconductor; step (D) of forming a pair of a source electrode and a drain electrode by forming a metal film on the gate insulating film and on the channel layer and partly removing the metal film formed on the channel layer by etching; and step (E) of forming the alignment film that includes at least one selected from the group consisting of a cinnamate structure, a chalcone structure, an azobenzene structure, a stilbene structure, a coumarin structure, and a phenyl ester structure, the step (E) including irradiation with light having a wavelength of 270 nm or longer. According to the aspect, the alignment treatment can be performed by irradiation with light having a wavelength of 270 nm or longer, and therefore, photoexcitation of the defect level of the oxide semiconductor included in the channel layer can be prevented in the thin-film transistor having a channel etch structure. In this manner, degradation of the current-voltage (I-V) characteristics of the TFT due to the photo-alignment treatment can be prevented. This can prevent nonuniform DC charging due to TFT characteristics, leading to production of a liquid crystal display device excellent in display quality.

The method for producing a liquid crystal display device may further include step (F) of forming a polymer layer by irradiating a liquid crystal material that contains a precursor including at least one of an acrylate monomer and a methacrylate monomer and liquid crystal molecules, with light having a wavelength of 270 nm or longer to polymerize the precursor. Such a method of forming a polymer layer is referred to as polymer sustained alignment (PSA). The precursor is suitably used as it can be efficiently radically polymerized with light having a wavelength of 270 nm or longer. The polymer prepared by radical polymerization has lower solubility into a liquid crystal material than the precursor, and therefore can be formed into a film as a polymer layer on the thin-film transistor substrate.

The technical features of the present invention described above may be appropriately combined within the spirit of the present invention.

### REFERENCE SIGNS LIST

10: Backlight
20: Thin-film transistor (TFT) substrate
21: Substrate
22: Gate line
22g: Gate electrode
23: Gate insulating film
24: Channel layer
25: Source line
25d: Drain electrode
25s: Source electrode
26: Channel protection film
27: Acrylic resin film
28: Auxiliary capacitance electrode
29: Auxiliary capacitance insulating film
30: Pixel electrode
40: Color filter (CF) substrate
50: Alignment film
60: Liquid crystal layer

1. A liquid crystal display device comprising:
a thin-film transistor substrate; and
a liquid crystal layer,
the thin-film transistor substrate comprising a thin-film transistor having a channel etch structure and an alignment film,
the thin-film transistor comprising a gate electrode, a gate insulating film, a channel layer containing an oxide semiconductor, and a pair of a source electrode and a drain electrode in the stated order,
the alignment film comprising at least one selected from the group consisting of a cinnamate structure, a chalcone structure, an azobenzene structure, a stilbene structure, a coumarin structure, and a phenyl ester structure.

2. The liquid crystal display device according to claim 1,
wherein the oxide semiconductor contains indium, gallium, zinc, and oxygen.

3. The liquid crystal display device according to claim 1, further comprising
a polymer layer including at least one of an acrylate structure and a methacrylate structure between the alignment film and the liquid crystal layer.

4. The liquid crystal display device according to claim 1,
wherein the thin-film transistor substrate includes a pair of electrodes configured to apply an electric field to the liquid crystal layer.

5. The liquid crystal display device according to claim 1,
wherein the display mode of the liquid crystal display device is a vertical alignment twisted nematic mode.

6. A method for producing a liquid crystal display device including a thin-film transistor substrate that includes a bottom gate type thin-film transistor and an alignment film, and a liquid crystal layer, comprising:
step (A) of forming a gate electrode;
step (B) of forming a gate insulating film;
step (C) of forming a channel layer containing an oxide semiconductor;
step (D) of forming a pair of a source electrode and a drain electrode by forming a metal film on the gate insulating film and on the channel layer and partly removing the metal film formed on the channel layer by etching; and
step (E) of forming the alignment film that includes at least one selected from the group consisting of a cinnamate structure, a chalcone structure, an azobenzene structure, a stilbene structure, a coumarin structure, and a phenyl ester structure,
the step (E) including irradiation with light having a wavelength of 270 nm or longer.

7. The method for producing a liquid crystal display device according to claim 6, further comprising
step (F) of forming a polymer layer by irradiating a liquid crystal material that contains a precursor including at least one of an acrylate monomer and a methacrylate monomer and liquid crystal molecules, with light having a wavelength of 270 nm or longer to polymerize the precursor.
